(19) United States
(12) Patent Application Publication
(10) Pub. No.: US 2025/0069949 A1
(43) Pub. Date: Feb. 27, 2025

(54) METHOD FOR REDUCING RESISTANCE OF CONTACT

(71) Applicant: Shanghai Huali Integrated Circuit Corporation, Shanghai (CN)

(72) Inventors: Zhaoqin ZENG, Shanghai (CN); Yu ZHANG, Shanghai (CN); Jingxun FANG, Shanghai (CN); Yu BAO, Shanghai (CN)

(73) Assignee: Shanghai Huali Integrated Circuit Corporation, Shanghai (CN)

(21) Appl. No.: 18/778,736

(22) Filed: Jul. 19, 2024

(30) Foreign Application Priority Data
Aug. 24, 2023 (CN) 202311075422.0

(51) Int. Cl. H01L 21/768; H01L 23/522; H01L 23/532

(52) U.S. Cl. CPC H01L 21/76876; H01L 21/76877; H01L 23/5226; H01L 23/53266

(57) ABSTRACT

The present disclosure provides a method for reducing a resistance of a contact, including: preparing a via in a device structure, and fabricating an adhesive layer that is in the via and attached to an inner wall of the via; fabricating a metal film that is in the via and attached to the adhesive layer; and filling the via with metal tungsten. In the present application, from the point of view of reducing high-resistance metals Ti and TiN and increasing low-resistance metal tungsten, a fluorine-free chemical is used to replace WF₆ to participate in a reaction of a W film, forming a tungsten film which replaces a TiN film, increasing the volume of tungsten, and reducing a via resistance.

### CROSS-REFERENCE TO RELATED APPLICATIONS

This application claims priority to Chinese patent application No. 202311075422.0, filed on Aug. 24, 2023, the disclosure of which is incorporated herein by reference in its entirety.

### TECHNICAL FIELD

The present disclosure relates to the technical field of semiconductors, and in particular to a method for reducing a resistance of a contact.

### BACKGROUND

Currently, there are two methods for improving the performance of a device, one is to optimize the efficiency of the device, and the other is to optimize the parasitic capacitance and resistance to reduce an RC latency of a wire. As the technology node of the integrated circuit process becomes increasingly small, via resistance reduction is particularly important for improving the device performance.

At present, via metals are Ti, TiN, and W sequentially from the outside to the inside. The Ti metal acts as an adhesive layer, TiN acts as a barrier layer to prevent a reactant gas WF₆ from corroding the Ti metal during a W process, and an innermost W layer has a minimum resistivity. Since the high-resistance metals Ti and TiN occupy a large space, the via resistance is large. The main reasons why the industry fails to compress the amount of the high-resistance metals are as follows. First, W and SiO₂ are prone to peeling off, and the Ti metal is required to act as the adhesive layer. Second, the W process is achieved by a reaction between WF₆ and B₂H₆/H₄Si/H₂, and a “volcano” defect occurs when WF₆ contacts Ti directly.

### BRIEF SUMMARY

The present disclosure provides a method for reducing a resistance of a contact, at least including:
step I, preparing a via in a device structure, and fabricating an adhesive layer that is in the via and attached to an inner wall of the via;
step II, fabricating a metal film that is in the via and attached to the adhesive layer, the metal film being a tungsten film; and
step III, filling the via with metal tungsten.

In some examples, the adhesive layer in step I is a Ti layer, a TiN layer, or a composite layer of a Ti layer and a TiN layer.

In some examples, the adhesive layer is fabricated by means of physical vapor deposition in step I.

In some examples, the metal film is obtained by means of a reaction with a fluorine-free chemical in step II.

In some examples, the fluorine-free chemical in step II is WCL₅.

In some examples, the tungsten film is formed by means of a reaction between WCL₅ and hydrogen in step II.

In some examples, the via is filled with the metal tungsten by means of a fluorine-containing reaction in step III.

In some examples, the metal tungsten is formed by means of a reaction between WF₆ and B₂H₆ or SiH₄ in step III.

In some examples, the metal tungsten is formed by means of a reaction between WF₆ and H₂ in step III.

In some examples, the metal tungsten is formed by two steps in step III: forming a tungsten layer attached to the metal film by means of a reaction between WF₆ and B₂H₆ or SiH₄ in a first step, and forming bulk layer tungsten by means of a reaction between WF₆ and H₂ in a second step.

As described above, the method for reducing a resistance of a contact of the present disclosure has the following beneficial effects: in the present disclosure, from the point of view of reducing high-resistance metals Ti and TiN and increasing low-resistance metal tungsten, a fluorine-free chemical is used to replace WF₆ to participate in a reaction of a W film. Accordingly, the formation of a TiN film is avoided, increasing the volume of tungsten, and reducing a via resistance.

### BRIEF DESCRIPTION OF THE DRAWINGS

FIG. 1 illustrates a schematic top view of a contact formed by fabricating an adhesive layer and a metal film and filling with metal tungsten in a via of the present disclosure; and

FIG. 2 illustrates a flowchart of a method for reducing a resistance of a contact of the present disclosure.

### DETAILED DESCRIPTION OF THE DISCLOSURE

The embodiments of the present disclosure are described below using specific examples, and those skilled in the art could readily understand other advantages and effects of the present disclosure from the contents disclosed in the description. The present disclosure can also be implemented or applied using other different specific implementations, and various details in the description can also be modified or changed based on different viewpoints and disclosures without departing from the spirit of the present disclosure.

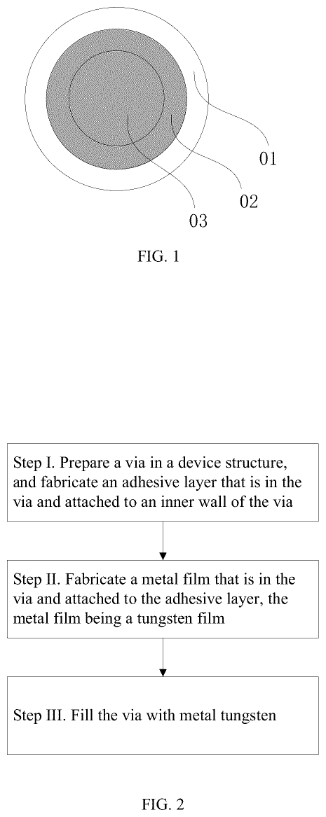

References are made to FIGS. 1 to 2. It should be noted that the drawings provided in the embodiments are only used to illustrate the basic concept of the present disclosure in a schematic way, so the drawings only show the components related to the present disclosure rather than being drawn according to the number, shape, and size of the components in actual implementations. The type, number, and proportion of various components can be changed randomly in the actual implementations, and the layout of the components may be more complicated.

The present disclosure provides a method for reducing a resistance of a contact. Referring to FIG. 2, FIG. 2 illustrates a flowchart of the method for reducing a resistance of a contact of the present disclosure. The method at least includes the following steps.
Step I. A via in a device structure is prepared, and an adhesive layer that is in the via and attached to an inner wall of the via is fabricated.

Furthermore, in this embodiment of the present disclosure, the adhesive layer in step I is a Ti layer, a TiN layer, or a composite layer of a Ti layer and a TiN layer.

Furthermore, in this embodiment of the present disclosure, the adhesive layer is fabricated by means of physical vapor deposition in step I.

Referring to FIG. 1, FIG. 1 illustrates a schematic top view of a contact formed by fabricating the adhesive layer and metal film and filling with metal tungsten in the via of the present disclosure, i.e., a cross-sectional view. In step I, the via in the device structure is prepared, the via being a hollow hole structure connecting upper and lower layers of the device; and then the adhesive layer 01 that is in the via and attached to the inner wall of the via is fabricated. The adhesive layer in this embodiment is a Ti layer, a TiN layer, or a composite layer of a Ti layer and a TiN layer. Furthermore, in this embodiment, the adhesive layer is fabricated by means of the physical vapor deposition.
Step II. A metal film that is in the via and attached to the adhesive layer is fabricated, the metal film being a tungsten film,

Furthermore, in this embodiment of the present disclosure, the metal film is obtained by means of a reaction with a fluorine-free chemical in step II.

Furthermore, in this embodiment of the present disclosure, the fluorine-free chemical in step II is WCL₅.

Furthermore, in this embodiment of the present disclosure, the tungsten film is formed by means of a reaction between WCL₅ and hydrogen in step II.

Referring to FIG. 1, in step II, the metal film 02 that is in the via and attached to the adhesive layer 01 is fabricated, the metal film being the tungsten film, and the metal film being obtained by means of the reaction with the fluorine-free chemical. In some examples, the fluorine-free chemical is WCL₅. Furthermore, the tungsten film is formed by means of the reaction between WCL₅ and hydrogen.
Step III. The via is filled with metal tungsten.

Furthermore, in this embodiment of the present disclosure, the via is filled with the metal tungsten by means of a fluorine-containing reaction in step III.

Furthermore, in this embodiment of the present disclosure, the metal tungsten is formed by means of a reaction between WF₆ and B₂H₆ or SiH₄ in step III.

Furthermore, in this embodiment of the present disclosure, the metal tungsten is formed by means of a reaction between WF₆ and H₂ in step III.

The metal tungsten is formed by two steps in step III: forming a tungsten layer attached to the metal film by means of a reaction between WF₆ and B₂H₆ or SiH₄ in a first step, and forming bulk layer tungsten by means of a reaction between WF₆ and H₂ in a second step.

Referring to FIG. 1, in step III, the via is filled with the metal tungsten 03. In the present disclosure, the via is filled with the metal tungsten by means of the fluorine-containing reaction, and in some embodiments, the metal tungsten is formed by means of the reaction between WF₆ and B₂H₆ or SiH₄. In some embodiments, the metal tungsten may also be formed by means of the reaction between WF₆ and H₂. In this embodiment, the metal tungsten is formed by two steps: forming the tungsten layer attached to the metal film 02 by means of the reaction between WF₆ and B₂H₆ or SiH₄ in the first step, and forming the bulk layer tungsten by means of the reaction between WF₆ and H₂ in the second step. FIG. 1 does not show the tungsten layer or the bulk layer tungsten separately. In the present disclosure, the via is filled with the tungsten layer formed in the first step and the bulk layer tungsten formed in the second step.

To sum up, in the present application, from the point of view of reducing high-resistance metals Ti and TiN and increasing low-resistance metal tungsten, a fluorine-free chemical is used to replace WF₆ to participate in a reaction of a W film, forming a tungsten film which replaces a TiN film, increasing the volume of tungsten, and reducing a via resistance. Therefore, the present disclosure effectively overcomes various defects in the prior art and has high industrial utilization value.

The above embodiments merely illustrate the principle and effect of the present disclosure, rather than limiting the present disclosure. Any person skilled in the art can modify or change the above embodiments without departing from the spirit and scope of the present disclosure. Therefore, all equivalent modifications or changes made by those with ordinary knowledge in the art without departing from the spirit and technical idea disclosed in the present disclosure shall still be covered by the claims of the present disclosure.

What is claimed is:

1. A method for reducing a resistance of a contact, at least comprising:
step I, preparing a via in a device structure, and fabricating an adhesive layer that is in the via and attached to an inner wall of the via;
step II, fabricating a metal film that is in the via and attached to the adhesive layer, the metal film being a tungsten film; and
step III, filling the via with metal tungsten.

2. The method for reducing a resistance of a contact according to claim 1, wherein the adhesive layer in step I is a Ti layer, a TiN layer, or a composite layer of a Ti layer and a TiN layer.

3. The method for reducing a resistance of a contact according to claim 1, wherein the adhesive layer is fabricated by means of physical vapor deposition in step I.

4. The method for reducing a resistance of a contact according to claim 1, wherein the metal film is obtained by means of a reaction with a fluorine-free chemical in step II.

5. The method for reducing a resistance of a contact according to claim 4, wherein the fluorine-free chemical in step II is WCL₅.

6. The method for reducing a resistance of a contact according to claim 5, wherein the tungsten film is formed by means of a reaction between WCL₅ and hydrogen in step II.

7. The method for reducing a resistance of a contact according to claim 1, wherein the via is filled with the metal tungsten by means of a fluorine-containing reaction in step III.

8. The method for reducing a resistance of a contact according to claim 7, wherein the metal tungsten is formed by means of a reaction between WF₆ and B₂H₆ or SiH₄ in step III.

9. The method for reducing a resistance of a contact according to claim 7, wherein the metal tungsten is formed by means of a reaction between WF₆ and H₂ in step III.

10. The method for reducing a resistance of a contact according to claim 7, wherein the metal tungsten is formed by two steps in step III: forming a tungsten layer attached to the metal film by means of a reaction between WF₆ and B₂H₆ or SiH₄ in a first step, and forming bulk layer tungsten by means of a reaction between WF₆ and H₂ in a second step.
